(19) United States
(12) Patent Application Publication
(10) Pub. No.: US 2006/0152905 A1
(43) Pub. Date: Jul. 13, 2006

(54) Plasma display module

(75) Inventors: Sok-San Kim, Suwon-si (KR); Ki-Jung Kim, Suwon-si (KR); Tae-Kyoung Kang, Suwon-si (KR); Myoung-Kon Kim, Suwon-si (KR); Won-Sung Kim, Suwon-si (KR)

Correspondence Address: LEE & MORSE, P.C., 1101 WILSON BOULEVARD, SUITE 2000, ARLINGTON, VA, 22209, US

(73) Assignee: Samsung SDI Co., Ltd.

(21) Appl. No.: 11/326,614

(22) Filed: Jan. 6, 2006

(30) Foreign Application Priority Data
Jan. 6, 2005 (KR) 10-2005-0001137

(51) Int. Cl. H05K 7/20

(52) U.S. Cl. 361/715

(57) ABSTRACT

A plasma display module includes a chassis base, a plasma display panel for displaying an image, the plasma display panel disposed in front of the chassis base and supported by the chassis base, and a sheet stack interposed between the plasma display panel and the chassis base, wherein the sheet stack includes an anti-vibration sheet and a heat dissipation sheet.

### BACKGROUND OF THE INVENTION

1. Field of the Invention

The present invention relates to a plasma display module. In particular, the present invention relates to a plasma display module that can increase the heat dissipation efficiency and reduce the driving noise of a plasma display panel therein.

2. Description of the Related Art

A plasma display panel (PDP) is a flat panel display device that displays images using a discharge effect. Due to its desirable characteristics, such as high display capacity, high brightness, high contrast, clear latent image, large viewing angle, thinness and large screen size, the PDP is considered to be one of the next generation display devices that will replace the cathode ray tube.

FIG. 1 illustrates an exploded perspective view of a conventional plasma display module. Referring to FIG. 1, the plasma display module may include a PDP 30 and a chassis base 50 located facing the PDP 30. The PDP 30 may be an image displaying unit that displays an image by plasma discharge, and may include a front panel 10 and a rear panel 20 coupled facing each other.

Significant amounts of heat may be generated in the PDP 30, arising from the plasma discharge used to display the image. Therefore, a thermal conductive member 40 may be interposed between the PDP 30 and the chassis base 50, so that the heat generated in the PDP 30 may be readily transferred to the chassis base 50. An adhesive member 45, e.g., double-sided tape, may be attached along the circumference of the thermal conductive member 40. The plasma display module may be assembled by pressing the PDP 30 and the chassis base 50 together while the thermal conductive member 40 and the adhesive member 45 are interposed therebetween.

An adhesive layer 80 may be interposed between the PDP 30 and the thermal conductive member 40 to fix the thermal conductive member 40 between the PDP 30 and the chassis base 50. However, heat generated by the PDP 30 may not be transferred to the chassis base 50 rapidly enough, since the adhesive layer 80 may exhibit a low thermal conductivity and may be located on the heat transfer path between the PDP 30 and the chassis base 50. Accordingly, significant amounts of heat may accumulate in the PDP 30. The accumulation of excessive heat may result in the degradation of a phosphor layer (not shown) in the PDP 30, thereby reducing image qualities such as brightness, etc.

FIG. 2 illustrates a cross-section taken along line II-II of FIG. 1. FIG. 2 also includes an enlarged cross-section, denoted by the dashed circle. In the enlarged cross-section, the adhesive layer 80 is omitted for clarity of illustration. Referring to FIG. 2, the PDP 30 may include the front panel 10 and the rear panel 20 coupled facing each other. The front panel 10 may include a front substrate 11, discharge sustain electrode pairs 16 formed on the front substrate 11, and a front dielectric layer 14 covering the sustain discharge electrode pairs 16. The front panel 10 may further include a protection layer 15, e.g., a MgO layer, disposed to cover the front dielectric layer 14.

The rear panel 20 may include a rear substrate 21, address electrodes 22 formed on the rear substrate 21, a rear dielectric layer 23 covering the address electrodes 22, a barrier rib 24 that defines a plurality of discharge spaces 26, and a phosphor layer 25 formed along the barrier rib 24 and the rear dielectric layer 23.

When a predetermined alternating current voltage, large enough to cause discharge, is applied to the discharge sustain electrode pairs 16, a display discharge may be generated between the discharge sustain electrode pairs 16. Plasma generated as the result of the display discharge may then excite the phosphor layer 25, causing it to emit the visible light that forms the image. A discharge gas may be filled in the discharge spaces 26, and, during operation, a vibration may be continuously generated as the discharge pressure of the discharge gas periodically changes with the display discharge. However, in the conventional plasma display module, a vibration absorbing structure is not provided. Therefore, the vibration may be transmitted to the outside, causing audible noise.

### SUMMARY OF THE INVENTION

The present invention is therefore directed to a plasma display module, which may increase the heat dissipation efficiency and/or reduce the driving noise of a plasma display panel therein, and which substantially overcomes one or more of the problems due to the limitations and disadvantages of the related art.

It is therefore a feature of an embodiment of the present invention to provide a plasma display module that can prevent localized high temperatures in a plasma display panel and that increases the efficiency of heat dissipation.

It is therefore another feature of an embodiment of the present invention to provide a plasma display module that can reduce driving noise of a plasma display panel therein.

At least one of the above and other features and advantages of the present invention may be realized by providing a plasma display module including a chassis base, a plasma display panel for displaying an image, the plasma display panel disposed in front of the chassis base and supported by the chassis base, and a sheet stack interposed between the plasma display panel and the chassis base, wherein the sheet stack includes an anti-vibration sheet and a heat dissipation sheet.

The plasma display module may further include a circuit unit located at the rear of the chassis base and supported by the chassis base, the circuit unit for driving the plasma display panel. The anti-vibration sheet may be interposed between the plasma display panel and the heat dissipation sheet, and the heat dissipation sheet may be interposed between the chassis base and the anti-vibration sheet. The heat dissipation sheet may be interposed between the plasma display panel and the anti-vibration sheet, and the anti-vibration sheet may be interposed between the chassis base and the heat-dissipation sheet.

The plasma display panel and the chassis base may be coupled to each other by an adhesive member disposed along an outer circumference of the sheet stack. The adhesive member may contact the plasma display panel and the chassis base and may not contact the sheet stack. The adhesive member may be double-sided tape. The installed thickness of the adhesive member may be equal to the sum of the installed thicknesses of the anti-vibration sheet and the heat dissipation sheet.

The anti-vibration sheet and the heat dissipation sheet may be disposed directly adjacent to one another. The plasma display module may be disposed directly adjacent to the sheet stack and the sheet stack may be disposed directly adjacent to the chassis base. The anti-vibration sheet and the heat dissipation sheet may be attached to each other. The anti-vibration sheet and the heat dissipation sheet may be attached to each other by an adhesive disposed therebetween.

The anti-vibration sheet may be formed of a silicone rubber composite. The anti-vibration sheet may include a thermally conductive filler. The thermally conductive filler may include one or more of a metal powder and a metal oxide powder. The thermally conductive filler may include one or more of Cu, Ag, Al, Al₂O₃, and SiO₂. The heat dissipation sheet may be metal or graphite. The anti-vibration sheet and the heat dissipation sheet may have substantially the same length and width dimensions.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 illustrates an exploded perspective view of a conventional plasma display module;

FIG. 2 illustrates a cross-section taken along line II-II of FIG. 1;

FIG. 3 illustrates an exploded perspective view of a plasma display module according to an embodiment of the present invention;

FIG. 4 illustrates a cross-section taken along line IV-IV of FIG. 3;

FIG. 5 illustrates a vertical cross-section of a plasma display module according to another embodiment of the present invention; and

FIG. 6 illustrates a perspective view of a sheet stack according to still another embodiment of the present invention.

### DETAILED DESCRIPTION OF THE INVENTION

Korean Patent Application No. 10-2005-0001137, filed on Jan. 6, 2005, in the Korean Intellectual Property Office, and entitled, “Plasma Display Module,” is incorporated by reference herein in its entirety.

The present invention will now be described more fully hereinafter with reference to the accompanying drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the figures, the dimensions of layers and regions are exaggerated for clarity of illustration. It will also be understood that when a layer is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

The plasma display module according to the present invention may include a sheet stack interposed between the PDP and the chassis base. The sheet stack may include an anti-vibration sheet to absorb driving noise caused by plasma discharge and may include a heat dissipation sheet.

Further, the reduction of heat dissipation efficiency introduced by the conventional adhesive layer affixing the thermal conductive member may be avoided by eliminating the adhesive layer, which may have a relatively low thermal conductivity. Accordingly, effects on the displayed images, e.g., brightness differences, or permanent degradation of the PDP caused by locally accumulated heat, may be reduced or prevented.

In addition, disassembly and repair of the plasma display module may be simplified and the dissembled parts may be reused. That is, disassembly of the plasma display module for repair of the PDP, chassis base, or elements mounted thereon is generally performed manually. However, in the conventional plasma display module, it may be difficult to separate the PDP from thermally conductive members. For example, a heating apparatus may be required for removing the adhesive layer in the conventional display. However, according to the present invention, the adhesive layer may be eliminated from the assembly, thereby allowing the plasma display module to be easily disassembled.

Moreover, the heat dissipation efficiency of the plasma display module may be enhanced since the PDP may tightly contact the sheet stack. The anti-vibration sheet in the sheet stack may absorb driving noise and may also serve a buffering function. The sheet stack may be tightly compressed between the plasma display panel and the chassis base and may tightly contact them. Therefore, the occurrence of air gaps may be reduced or eliminated when coupling the PDP and the chassis base.

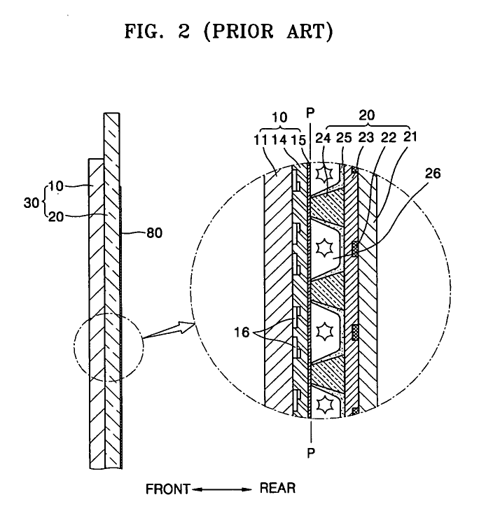

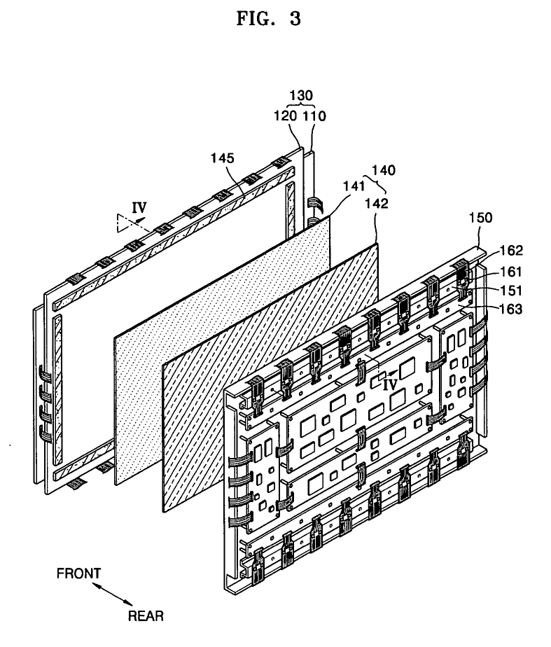

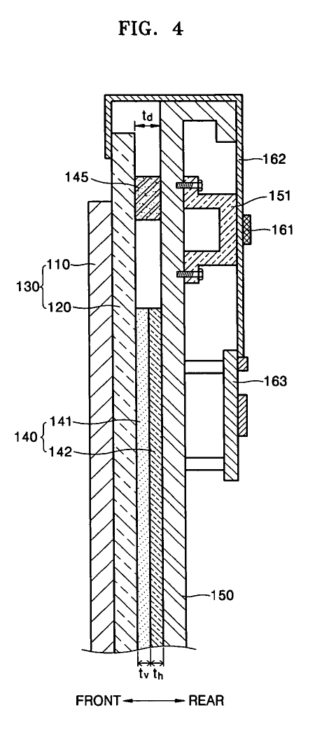

FIG. 3 illustrates an exploded perspective view of a plasma display module according to an embodiment of the present invention, and FIG. 4 illustrates a cross-section taken along line IV-IV of FIG. 3. Referring to FIG. 3, a plasma display module may include a chassis base 150 and a PDP 130 for displaying an image, which may be located in front of and may be supported by the chassis base 150. The chassis base 150 may support the PDP 130. As the PDP 130 may be formed of, e.g., glass, it may be heavy. Accordingly, a reinforcing member 151 for reinforcing the chassis base 150 may be mounted on the chassis base 150. The PDP 130 may be configured as described above with reference to FIG. 2.

The chassis base 150 may include a circuit unit for driving the PDP 130, which may be mounted on and supported by a rear surface of the chassis base 150. The circuit unit may include circuit substrates 163 for driving the PDP 130. The circuit substrates 163 may include a plurality of circuit devices that generate predetermined driving signals. The driving signals generated from the circuit devices may be applied to the PDP 130 through connection cables 162 which extend forward from the circuit substrates 163. The connection cables 162 may include integrated circuit chips 161 that transform the driving signals.

A sheet stack 140 may be interposed between the chassis base 150 and the PDP 130. The sheet stack 140 may include a plurality of sheets, e.g., an anti-vibration sheet 141 and a heat dissipation sheet 142. The chassis base 150 may function as a heat dissipation plate for the PDP 130. Therefore, the chassis base 150 may formed of a material exhibiting a high thermal conductivity, e.g., aluminum. The sheet stack 140 may be thermally conductive and may be located between the chassis base 150 and the PDP 130, such that heat generated by the PDP 130 may be transferred to the chassis base 150 through the sheet stack 140.

The sheet stack 140 may be interposed between the chassis base 150 and the PDP 130, and an adhesive member 145, e.g., double-sided tape, may be attached around the circumference of the sheet stack 140. When the chassis base 150 is coupled to the PDP 130, the sheet stack 140 may be tightly fixed therebetween by the adhesive member 145.

The anti-vibration sheet 141 may be interposed between the chassis base 150 and the PDP 130. The anti-vibration sheet 141 may have both thermal conductivity and anti-vibration characteristics. The anti-vibration sheet 141 may act as a heat path to conduct heat between the PDP 130 and the heat dissipation sheet 142. Further, the anti-vibration sheet 141 may absorb and dissipate discharge vibrations of the PDP 130.

The anti-vibration sheet 141 may be formed of, e.g., a silicone rubber sheet. The silicone rubber sheet may be a thermally conductive silicone rubber composite formed of silicone resin in a matrix form and containing a thermally conductive filler. The thermally conductive filler may be, e.g., a metal such as Cu, Ag, Al, etc., a metal oxide such as Al₂O₃, SiO₂, etc., and the like.

In another implementation, a porous carbon material may be used to form the anti-vibration sheet 141. An exemplary method of forming the anti-vibration sheet 141 of a porous carbon material will be described next, although the present invention is not limited to this exemplary method. In forming the anti-vibration sheet 141, a mixture may be formed by uniformly mixing a carbon material and a binder, after which the mixture may be molded into a sheet, the sheet hardened, and the sheet heated at a high temperature, e.g., higher than 1000° C., under an inert gas atmosphere. The carbon material may be, e.g., a powder of carbon fiber, petroleum cokes, etc., and the binder may be, e.g., a mixture of a thermally curable resin such as epoxy and a pitch of petroleum or coal.

In still another implementation, the anti-vibration sheet 141 may be formed of a metal having a high thermal conductivity, e.g., Al, Cu, Ag, Ni, etc. A plurality of pores may be formed in the metal by, e.g., foam processing. For example, a highly thermally conductive metal powder, a foam agent, and a binder may be mixed by fusion melting and formed into a sheet through a molding process. Then, the porous anti-vibration sheet 141 may be obtained by heating the sheet at a temperature of approximately 1500° C. under an inert gas atmosphere.

By interposing the anti-vibration sheet 141 having a buffering function between the PDP 130 and the chassis base 150, discharge vibrations generated by the PDP 130 may be absorbed and diffused by the anti-vibration sheet 141. Thus, driving noise caused by the vibrations may be diminished or blocked. Further, the anti-vibration sheet 141 may absorb vibrations that result when moving the plasma display module, thereby protecting the PDP 130, which may be formed of glass.

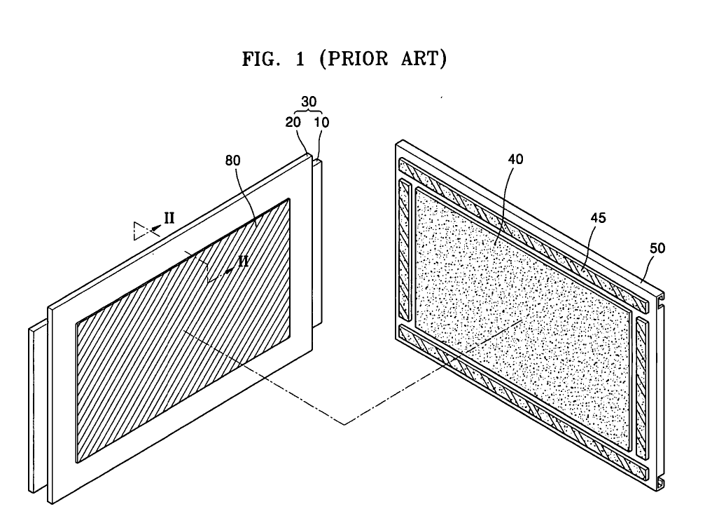

Since the anti-vibration sheet 141 may provide a buffering function between the PDP 130 and the chassis base 150, the sheet stack 140 may be tightly fixed therebetween. Accordingly, the additional adhesive layer depicted in FIG. 1, which is used for affixing the thermally conductive member in the conventional plasma display pane, is unnecessary. The elimination of this adhesive layer, which may exhibit a low thermal conductivity, may allow for increased heat dissipation efficiency of the PDP 130.

Furthermore, since the sheet stack 140 may be tightly fixed between the PDP 130 and the chassis base 150, heat generated from the PDP 130 may be rapidly transferred to the chassis base 150, even if the surfaces of the PDP 130 and/or the chassis base 150 are somewhat non-planar or distorted. Accordingly, the plasma display module according to the present invention may exhibit an enhanced heat dissipation efficiency.

The heat dissipation sheet 142, which may be located facing the anti-vibration sheet 141, may be formed of a material having high thermal conductivity such as a metal, e.g., Al, Cu, Ag, Ni, etc., or a highly-orientated graphite film. The heat dissipation sheet 142 may be, e.g., a metal plate. Where a highly-oriented graphite film is employed, the highly-orientated graphite film may have an anisotropic thermal conductivity characteristic. That is, the thermal conductivity of the film may be higher in the planar direction than in the thickness direction since graphite crystals in the film may be arranged in the plane direction. The highly-orientated graphite film may be formed by, e.g., annealing carbon atoms after the carbon atoms are deposited using a hydrocarbon gas by a chemical vapor deposition (CVD) method, or through graphitization of a carbonaceous polymer compound.

Where the thermally conductive heat dissipation sheet 142 is interposed between the PDP 130 and the chassis base 150, heat generated by the PDP 130 may be efficiently transferred to the chassis base 150. Also, the heat generated by the PDP 130 may be rapidly diffused in width and height directions of the PDP 130, resulting in a uniform temperature distribution across the PDP 130. Thus, the heat dissipation sheet 142 may reduce the occurrence or extent of localized high temperatures caused by a difference in discharge strengths in different regions of the PDP 130. This may improve the performance of the PDP 130 by, e.g., reducing a difference in brightness across different regions of the PDP 130.

Referring to FIG. 4, thicknesses tᵥ and tₕ of the anti-vibration sheet 141 and the heat dissipation sheet 142 may be determined according to specific design requirements for vibration reduction and heat dissipation in the plasma display module. For example, as the thickness tᵥ of the anti-vibration sheet 141 is increased, the anti-vibration characteristic may be increased. However, if the anti-vibration sheet 141 has a lower thermal conductivity than the heat dissipation sheet 142, and the anti-vibration sheet 141 is excessively thick, the heat dissipation characteristic of the plasma display module may be reduced. Therefore, the thickness of the anti-vibration sheet 141 may be restricted within a predetermined range. In FIG. 4, t_{d} represents the thickness of the adhesive member 145. The value of t_{d} may be set to be equal to the sum of the thicknesses tᵥ and tₕ of the anti-vibration sheet 141 and the heat dissipation sheet 142, respectively. That is, the installed thicknesses of the adhesive member 145, the anti-vibration sheet 141 and the heat dissipation sheet 142 may be set such that, in the assembled plasma display module, the thickness t_{d} may be equal to the sum of the thicknesses tᵥ and tₕ.

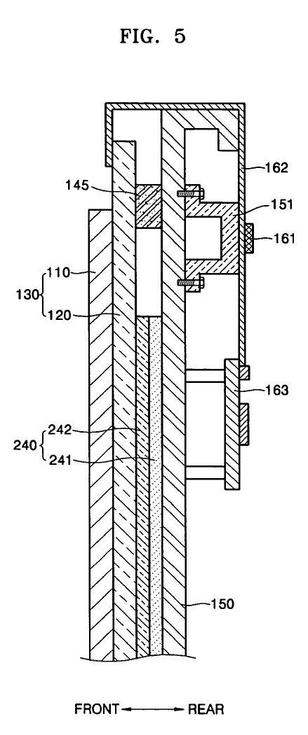

FIG. 5 illustrates a vertical cross-section of a plasma display module according to another embodiment of the present invention. Referring to FIG. 5, the plasma display module may include a PDP 130 on the front side and a chassis base 150 on the rear side of the plasma display module. A sheet stack 240 may be interposed between the PDP 130 and the chassis base 150. The sheet stack 240 may include a heat dissipation sheet 242 and an anti-vibration sheet 241 contacting and facing each other.

In this embodiment, the heat dissipation sheet 242 may be disposed to contact the PDP 130 and the anti-vibration sheet 241 may be disposed to contact the chassis base 150. The heat dissipation sheet 242 disposed to contact the PDP 130 may rapidly diffuse heat generated during the operation of the PDP 130 in the plane direction of the PDP 130. Thus, for example, when the PDP 130 displays a grey scale using differences between the number of discharges, a portion of the PDP 130 might exhibit localized hot spots. Localized accumulated heat may degrade portions of the PDP 130. Therefore, in the present embodiment, the heat dissipation sheet 242 having high thermal conductivity may be located adjacent to the PDP 130 to promote heat diffusion and reduce or prevent localized heat accumulation.

The PDP 130 and the chassis base 150 may be tightly coupled by pressed them together with the adhesive member 145 interposed therebetween. In the process of coupling, the anti-vibration sheet 241, which is pressed by the chassis base 150, may press the heat dissipation sheet 242 to make the heat dissipation sheet 242 tightly contact the PDP 130. Since the heat dissipation sheet 242 may tightly contact the PDP 130, the occurrence of an air gap therebetween may be reduced or prevented, thereby reducing the thermal resistance therebetween.

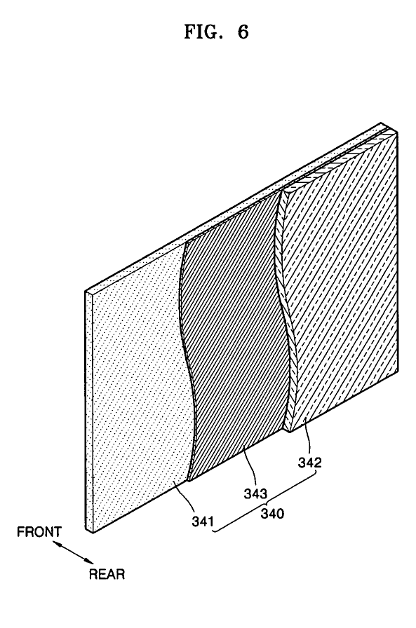

FIG. 6 illustrates a perspective view of a sheet stack according to still another embodiment of the present invention. Referring to FIG. 6, a sheet stack 340 may include an anti-vibration sheet 341 and a heat dissipation sheet 342 coupled facing each other. The anti-vibration sheet 341 and the heat dissipation sheet 342 may be coupled by an adhesive 343 disposed therebetween. In this case, the anti-vibration sheet 341 and the heat dissipation sheet 342 may be handled as a one body, to enable easy assembly of the plasma display module.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A plasma display module, comprising:
a chassis base;
a plasma display panel for displaying an image, the plasma display panel disposed in front of the chassis base and supported by the chassis base; and
a sheet stack interposed between the plasma display panel and the chassis base, wherein the sheet stack includes an anti-vibration sheet and a heat dissipation sheet.

2. The plasma display module as claimed in claim 1, further comprising a circuit unit located at the rear of the chassis base and supported by the chassis base, the circuit unit for driving the plasma display panel.

3. The plasma display module as claimed in claim 1, wherein the anti-vibration sheet is interposed between the plasma display panel and the heat dissipation sheet, and
the heat dissipation sheet is interposed between the chassis base and the anti-vibration sheet.

4. The plasma display module as claimed in claim 1, wherein the heat dissipation sheet is interposed between the plasma display panel and the anti-vibration sheet, and
the anti-vibration sheet is interposed between the chassis base and the heat-dissipation sheet.

5. The plasma display module as claimed in claim 1, wherein the plasma display panel and the chassis base are coupled to each other by an adhesive member disposed along an outer circumference of the sheet stack.

6. The plasma display module as claimed in claim 5, wherein the adhesive member contacts the plasma display panel and the chassis base and does not contact the sheet stack.

7. The plasma display module as claimed in claim 5, wherein the adhesive member is double-sided tape.

8. The plasma display module as claimed in claim 5, wherein the installed thickness of the adhesive member is equal to the sum of the installed thicknesses of the anti-vibration sheet and the heat dissipation sheet.

9. The plasma display module as claimed in claim 1, wherein the anti-vibration sheet and the heat dissipation sheet are disposed directly adjacent to one another.

10. The plasma display module as claimed in claim 9, wherein the plasma display module is disposed directly adjacent to the sheet stack and the sheet stack is disposed directly adjacent to the chassis base.

11. The plasma display module as claimed in claim 1, wherein the anti-vibration sheet and the heat dissipation sheet are attached to each other.

12. The plasma display module as claimed in claim 11, wherein the anti-vibration sheet and the heat dissipation sheet are attached to each other by an adhesive disposed therebetween.

13. The plasma display module as claimed in claim 1, wherein the anti-vibration sheet is formed of a silicone rubber composite.

14. The plasma display module as claimed in claim 1, wherein the anti-vibration sheet includes a thermally conductive filler.

15. The plasma display module as claimed in claim 14, wherein the thermally conductive filler includes one or more of a metal powder and a metal oxide powder.

16. The plasma display module as claimed in claim 14, wherein the thermally conductive filler includes one or more of Cu, Ag, Al, Al₂O₃, and SiO₂.

17. The plasma display module as claimed in claim 1, wherein the heat dissipation sheet is metal or graphite.

18. The plasma display module as claimed in claim 1, wherein the anti-vibration sheet and the heat dissipation sheet have substantially the same length and width dimensions.
